(19) United States
(12) Patent Application Publication
(10) Pub. No.: US 2007/0237195 A1
(43) Pub. Date: Oct. 11, 2007

(54) Light Source, Method for Controlling Light Source, and Method for Replacing Light Source

(75) Inventor: Kazunari Sekigawa, Nagano-shi (JP)

Correspondence Address: PAUL AND PAUL, 2000 MARKET STREET, SUITE 2900, PHILADELPHIA, PA, 19103, US

(73) Assignee: SHINKO ELECTRIC INDUSTRIES CO., LTD., Nagano-shi (JP)

(21) Appl. No.: 11/696,817

(22) Filed: Apr. 5, 2007

(30) Foreign Application Priority Data
Apr. 7, 2006 (JP) 2006-106456

(51) Int. Cl. H01S 3/13; H01S 5/00

(52) U.S. Cl. 372/29.011; 372/50.21

(57) ABSTRACT

In a light source constructed from a plurality of laser diodes, the overall light output of the light source is controlled based on calibration data which is generated for each pair consisting of any one of the plurality of laser diodes and a dedicated control board for controlling the light output of the one laser diode, and which defines a correspondence between the control value for driving the control board and the value of the light output of the laser diode measured when the control board is driven based on the control value, and when replacing a designated one of the laser diodes in the light source, the designated laser diode and its dedicated control board are replaced together with the corresponding calibration data.

### BACKGROUND OF THE INVENTION

1. Field of the Invention

The present invention relates to a light source constructed from a plurality of laser diodes, a method for controlling the light source, and a method for replacing a designated one of the plurality of laser diodes in the light source.

2. Description of the Related Art

A semiconductor laser light source constructed from a laser diode (LD) contains a photodiode (PD) for receiving light emitted from the laser diode and for controlling the intensity of light emission of the laser diode. To facilitate the construction of such a semiconductor laser light source, a module structure in which the laser diode and the photodiode are mounted in close proximity to each other is proposed, for example, in Japanese Unexamined Patent Publication NO. 2004-349320.

In a control board (control circuit) for driving such a semiconductor laser light source, negative feedback control is performed by using the result of detection that the photodiode outputs by detecting the intensity of light emission of the laser diode, and the intensity of light emission of the laser diode is thus controlled to a constant level. The circuit board that performs such negative feedback control is generally called an APC (Automatic Power Control) circuit. In the case of a discrete laser diode not constructed as a module, a negative feedback circuit must be constructed by mounting a photodiode in close proximity to the laser diode.

FIG. 8 is a diagram showing one prior art example of a control board for driving a semiconductor laser. It is to be understood that, throughout the several drawings given hereinafter, component elements having the same functions are designated by the same reference characters.

In a module 20 shown in FIG. 8, a laser diode LD and a photodiode PD are arranged in close proximity to each other, and the laser diode LD and the photodiode PD are optically coupled. The laser diode LD emits light when supplied with a current I_{LD} from a current source 26. The photodiode PD receives the light emitted from the laser diode LD, and outputs a current I_{PD} proportional to the light output of the laser diode LD. A current amplifier 23 has a current-voltage converting function as well as the function of amplifying the output current I_{PD} of the photodiode PD, and converts the output current I_{PD} of the photodiode PD into a voltage which is output. Since the current amplifier 23 has an extremely low input impedance, the output voltage of the current amplifier 23 varies linearly over a wide range with the light output of the laser diode LD. An error amplifier 24 compares the output voltage of the current amplifier 23 with a reference voltage Vref set by a control voltage setter 25. The current I_{LD} of the current source 26 is controlled by using the output of the error amplifier 24.

In the control board shown in FIG. 8 for controlling the semiconductor laser driving, negative feedback control is performed in the following manner, for example, when the light output of the laser diode LD increases. That is, when the light output of the laser diode LD increases, the output current I_{PD} of the photodiode PD increases, and hence, the output voltage of the current amplifier 23 increases. Then, since the output of the error amplifier 24 decreases, the current I_{LD} of the current source 26 decreases, and as a result, the light output of the laser diode LD decreases. With this control, the light output of the laser diode LD is controlled to a constant value that matches the reference voltage Vref.

It is known to construct a light source using a plurality of laser diodes (semiconductor lasers). FIG. 9 is a diagram showing one prior art example of the light source constructed using a plurality of laser diodes. In the illustrated example, the light source comprises n modules (where n is a natural number) each containing a photodiode and a laser diode (neither shown). Each module 20 is connected to an optical fiber 13 via a connector 12. The other end of the optical fiber 13 is connected to a connector 14. Light emitted from the laser diode contained in each module 20 is transmitted via the corresponding optical fiber 13 and bundled together in the connector 14. The light output of a generally used laser diode is on the order of several hundred milliwatts; by contrast, with the light source constructed using a plurality of laser diodes as described above, a light output of, for example, several watts or higher can be obtained. The light output of the laser diode in each module 20 is controlled by a control board 10 by negative feedback as earlier described.

FIG. 10 is a diagram showing one prior art example of the control board for driving the light source shown in FIG. 9. The principle of operation is the same as that described for the control board shown in FIG. 8. In the illustrated example, there are n modules 20 each containing a laser diode LD and a photodiode PD. The output currents I_{PD} of the photodiodes PDs contained in the respective modules 20 are summed for input to the current amplifier 23. The output of the error amplifier 24 is split into n paths for connection to the respective current sources 26-1 to 26-n which supply currents I_{LD} to the laser diodes LDs in the respective modules 20. In this way, when the light source is constructed from a plurality of laser diodes, the light output of the light source is controlled to a constant level by using the sum value of the output currents I_{PD} of the photodiodes PDs contained in the respective modules 20. That is, when the sum value of the output currents I_{PD} of the photodiodes PDs in the respective modules 20 increases, the currents I_{LD} that the current sources 26-1 to 26-n supply to the laser diodes LDs in the respective modules 20 decrease, and when the sum value of the output currents I_{PD} of the photodiodes PDs in the respective modules 20 decreases, the currents I_{LD} that the current sources 26-1 to 26-n supply to the laser diodes LDs in the respective modules 20 increase, thereby performing control so that the overall light output of the light source is maintained at a desired constant value.

Such a light source is used, for example, to produce light for exposing an exposure surface in a direct exposure apparatus (i.e., a maskless exposure apparatus) which forms a desired exposure pattern by direct exposure on the exposure surface of an exposure target moving relative to the light source. The direct exposure apparatus requires the use of a light source having a high output power (for example, several watts or higher) in order to produce light for exposure.

As one example of such a direct exposure apparatus, an apparatus that forms an exposure pattern by direct exposure using a Digital micromirror Device (DMD) is disclosed, for example, in Japanese Unexamined Patent Publication No. 10-112579. FIG. 11 is a diagram illustrating one prior art example of the direct exposure apparatus that uses the Digital Micromirror Device. When directly exposing the resist formed on an exposure target substrate 103 moving relative to the Digital Micromirror Device (DMD) 151, pattern data corresponding to the pattern to be exposed is generated by a pattern generator 152, and this pattern data is applied to the DMD 151. The pattern generator 152 operates in conjunction with a position sensor 153 that detects the position of the exposure target substrate 103 moving in relative fashion, and the pattern generator 152 thus generates the pattern data in a manner that is synchronized to the position of the exposure target substrate 103. The light source 102 projects light onto the DMD 151 through a diffusion plate 154 and a lens 155. The DMD 151 causes each of its micromirrors to tilt according to the pattern data, thereby suitably changing the reflection direction of the light incident on each micromirror of the DMD 151, and projects the thus controlled light through a lens 156 onto the resist on the exposure target substrate 103 to form the exposure pattern corresponding to the pattern data.

In such a direct exposure apparatus, the light source for projecting the light onto the exposure target substrate must be constructed to provide uniform and evenly distributed light over the entire surface of the exposure target substrate in order to achieve a good exposure result.

FIG. 12 is a diagram showing one prior art example of the light source used in the direct exposure apparatus. The light source 102 used in the direct exposure apparatus is constructed by arranging a plurality of point light sources 158 in a two-dimensional array in order to provide uniform illumination. Parallel rays of light from the point light sources 158 are passed through the diffusion plate 154 to eliminate any “unevenness in illuminance,” and the thus produced light is projected onto the DMD 151 in FIG. 11.

When the control board for driving the light source constructed from the plurality of laser diodes performs control so as to maintain the light output of the light source at a constant level based on the sum value of the output currents I_{PD} of the photodiodes PDs contained in the n modules 20, as shown in FIG. 10, no particular problem will occur as long as all the laser diodes LDs are operating normally. However, if m laser diodes LDs (where m is a natural number, 1≦m<n) have failed, the overall light output of the light source significantly decreases. Here, the control board continues to perform control so as to maintain the overall light output of the light source constant at the desired value, irrespective of the presence or absence of a failed laser diode LD. As a result, the light source is controlled so that the desired light output can be achieved using only the normally operating (n-m) laser diodes LDs, putting a greater strain on the normally operating laser diodes LDs. The increased strain will eventually lead to shortened lifetime or failure of the normally operating laser diodes LDs. This may end up having to replace a larger number of laser diodes LDs. For example, if such a situation occurs during the operation of the direct exposure apparatus, the exposure process line has to be stopped for an extended period in order to locate the faults and replace the faulty parts, the result being a very large economic loss.

Furthermore, if any one of the laser diodes LDs has failed, the failure tends to go unnoticed, since the desired output level is obtained for the light source as a whole. If the failure is noticed at all, it is difficult to locate the failed laser diode LD, and in some cases, it may not be possible to locate the failed laser diode LD, and the entire light source may have to be replaced.

Accordingly, in view of the above problem, it is an object of the present invention to provide a light source constructed from a plurality of laser diodes which can be replaced easily and quickly, a method for controlling the light source, and a method for replacing a designated one of the plurality of laser diodes in the light source.

### SUMMARY OF THE INVENTION

To achieve the above object, the present invention provides a light source constructed from a plurality of laser diodes, wherein the overall light output of the light source is controlled based on calibration data which is generated in advance for each pair consisting of any one of the plurality of laser diodes and a control board dedicated to the one laser diode to control the light output of the one laser diode, and which defines a correspondence between a control value for driving the control board and a value representing the actual light output of the one laser diode measured when the control board is driven based on the control value.

According to the present invention, a method for controlling a light source constructed from a plurality of laser diodes, comprises: for each pair consisting of any one of the plurality of laser diodes and a control board dedicated to the one laser diode to control the light output of the one laser diode, generating in advance calibration data that defines a correspondence between a control value for driving the control board and a value representing the actual light output of the one laser diode measured when the control board is driven based on the control value; and

controlling the overall light output of the light source based on the calibration data generated for each such pair.

The present invention also provides a method for replacing a designated one of the plurality of laser diodes in such a light source, wherein

the designated laser diode to be replaced and a control board dedicated to the designated laser diode to control the light output of the designated laser diode are respectively replaced with a new laser diode and a new control board dedicated to the new laser diode to control the light output of the new laser diode, and

among calibration data which, for each pair consisting of any one of the plurality of laser diodes and a control board dedicated to the one laser diode to control the light output of the one laser diode, defines a correspondence between a control value for driving the control board and a value representing the actual light output of the one laser diode measured when the control board is driven based on the control value, the calibration data being used for controlling the overall light output of the light source, the calibration data that has been used for controlling the light output of the designated laser diode is replaced with the calibration data generated for the pair consisting of the new laser diode and the new control board dedicated to the new laser diode to control the light output of the new laser diode.

The light source of the present invention may be used to produce light for exposing an exposure surface in a direct exposure apparatus which forms a desired exposure pattern by direct exposure on the exposure surface of an exposure target moving relative to the light source. In particular, when the direct exposure apparatus is an apparatus that forms the desired exposure pattern on the exposure surface by projecting the light from the light source onto a digital micromirror device and by directing the light reflected by the digital micromirror device to the exposure surface of the exposure target moving relative to the digital micromirror device, each of the laser diodes forming the light source is controlled so that the light source of the present invention illuminates the digital micromirror device with evenly distributed light.

### BRIEF DESCRIPTION OF THE DRAWINGS

The present invention will be more clearly understood from the description as set below with reference to the accompanying drawings, wherein:

FIG. 1 is a block diagram showing a light source according to a first embodiment of the present invention and a control board for driving the light source;

FIG. 2 is a block diagram showing the configuration of the control board shown in FIG. 1;

FIGS. 3 to 5 are diagrams for explaining the adjustment of circuit parameters for the circuit board according to the first embodiment of the present invention;

FIG. 6 is a block diagram showing a light source according to a second embodiment of the present invention and a control board for driving the light source;

FIG. 7 is a block diagram showing the configuration of the control board shown in FIG. 6;

FIG. 8 is a diagram showing one prior art example of a control board for driving a semiconductor laser;

FIG. 9 is a diagram showing one prior art example of a light source constructed using a plurality of laser diodes;

FIG. 10 is a diagram showing one prior art example of a control board for driving the light source shown in FIG. 9;

FIG. 11 is a diagram illustrating one prior art example of a direct exposure apparatus that uses a Digital Micromirror Device; and

FIG. 12 is a diagram showing one prior art example of a light source used in the direct exposure apparatus.

### DESCRIPTION OF THE PREFERRED EMBODIMENTS

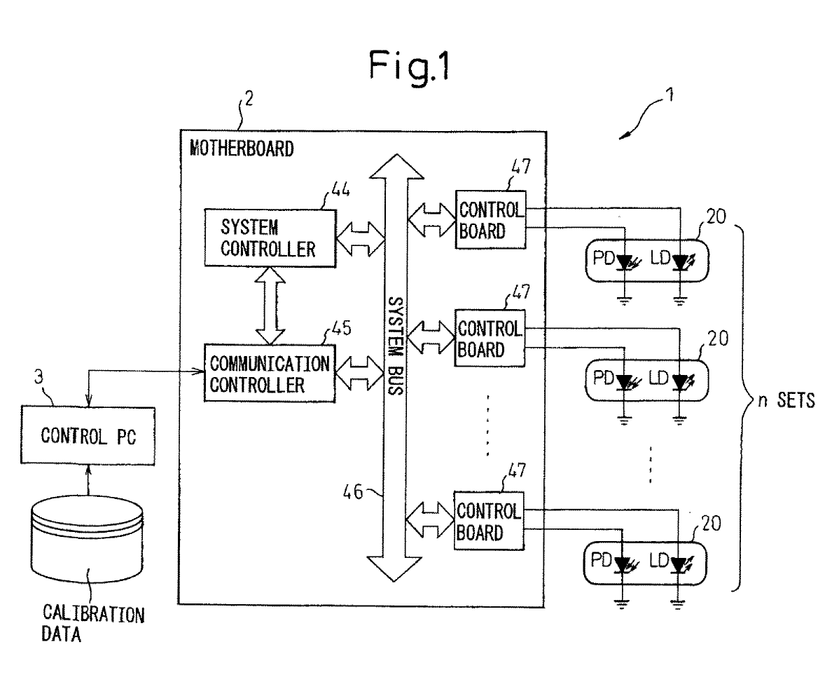

FIG. 1 is a block diagram showing a light source according to a first embodiment of the present invention and a control board for driving the light source. In the first embodiment, the light source 1 comprises n laser diodes. There are therefore a total of n modules 20, each containing a laser diode LD and a photodiode PD.

To drive the light source 1 comprising the n laser diodes LDs, each laser diode LD is provided with a dedicated control board 47 that controls the light output of the laser diode LD. Accordingly, there are a total of n control boards. The n control boards 47 which individually control the n laser diodes LDs are interconnected via a common system bus.

The control boards 47 are mounted on a motherboard 2. A communication controller 45 responsible for communicating with an external control PC (indicated at reference numeral 3) and a system controller 44 responsible for the overall control of the motherboard 2 are also mounted on the motherboard 2. The communication controller 45 controls data transfers between the external control PC 3 and the respective control boards 47 in response to instructions from the system controller 44.

Control software running on the control PC 3 reads calibration data hereinafter described, and controls the light outputs of the n laser diodes LDs by communicating with the motherboard 2.

The calibration data according to the present invention will be described below.

Each control board is driven based on a control value input to it. The control value is a parameter that the user sets and enters in advance so that the laser diode LD produces light at a desired output level. Accordingly, if the plurality of laser diodes LDs are operated to produce light by using the same control value, ideally all the laser diodes LDs should produce light with the same output level.

In reality, however, the output current I_{PD} of the photodiode PD somewhat differs from one module to another due to differences in the light detection sensitivity of each photodiode PD. Similarly, the light emission characteristic of the laser diode LD also differs from one module to another due to variations between different laser diodes LDs. Furthermore, circuit parameters differ between the control boards 47 provided for the different modules 20 (the respective laser diodes LDs) due to variations existing in the devices forming each control board 47. Accordingly, if the same control value is used, in actuality the light output levels of the respective laser diodes LDs differ from each other depending on the combination of the laser diode LD, photodiode PD, and control board 47. In the prior art, such variations in light output level among the laser diodes LDs have been resolved by manually adjusting each one of the circuit parameters such as resistance value, amplification factor, etc. in each circuit board.

The present invention uses the calibration data in order to eliminate the trouble of making such adjustments. The calibration data is a table that defines the correspondence between the control value for driving the control board 47 and the value of the actual light output of the laser diode LD measured when the control board 47 is driven based on the control value. To generate the calibration data, the actual light output of the laser diode LD must be measured by actually applying the control value to the control board 47, but it will be understood by those skilled in the art that a measuring apparatus, i.e., an apparatus (for example, a computer) for applying the control value to the control board 47, can be readily implemented using the known art.

Table 1 is a table that illustrates by way of example the correspondence between the control value X, where X is an integer (that is, a discrete value) ranging from 0 to 1023, and the measured value P₀(X) of the actual light output of the laser diode LD when the control board 47 is driven based on the control value X.

TABLE 1

| CONTROL | LIGHT OUTPUT MEASURED VALUE |
|---|---|
| VALUE X | Po (X) [mW] |
| 0 | −1.00 |
| 1 | −1.00 |
| 2 | −1.00 |
| . | −1.00 |
| . | −1.00 |
| 100 | −1.00 |
| 101 | 200.00 |
| 102 | 198.13 |
| . | . |
| . | . |
| . | . |
| 199 | 101.27 |
| 200 | 100.76 |
| 201 | 100.26 |
| . | . |
| . | . |
| 800 | 25.19 |
| . | . |
| . | . |
| . | . |
| 1023 | 19.70 |

Once the combination of the laser diode LD, photodiode PD, and control board 47 is determined, the control value X and the measured value P₀(X) of the actual light output of the laser diode LD can be determined on a one-to-one basis; therefore, the calibration data is generated for each combination of the laser diode LD and its dedicated control board 47 provided for controlling the light output of that laser diode.

The calibration data thus generated for each combination of the laser diode LD, photodiode PD, and control board 47 is prestored in a database connected to the control PC 3 in FIG. 1. The control software running on the control PC 3 reads the calibration data for each particular combination, and controls the light output of the corresponding laser diode LD by communicating with the motherboard 2.

In the first embodiment of the present invention, when replacing any one of the plurality of laser diodes LDs in the light source 1, the laser diode LD and the control board 47 dedicated to that laser diode are replaced together with the corresponding calibration data. This will be described in further detail. That is, the laser diode to be replaced and the control board dedicated to that laser diode are respectively replaced with a new laser diode and a new control board dedicated to that new laser diode. As for the calibration data, the calibration data that has been used for controlling the light output of the laser diode to be replaced is replaced with calibration data generated for the combination of the new laser diode and the new control board dedicated to that new laser diode. The replacement of the calibration data can be accomplished, for example, by the user entering the data on the control PC 3.

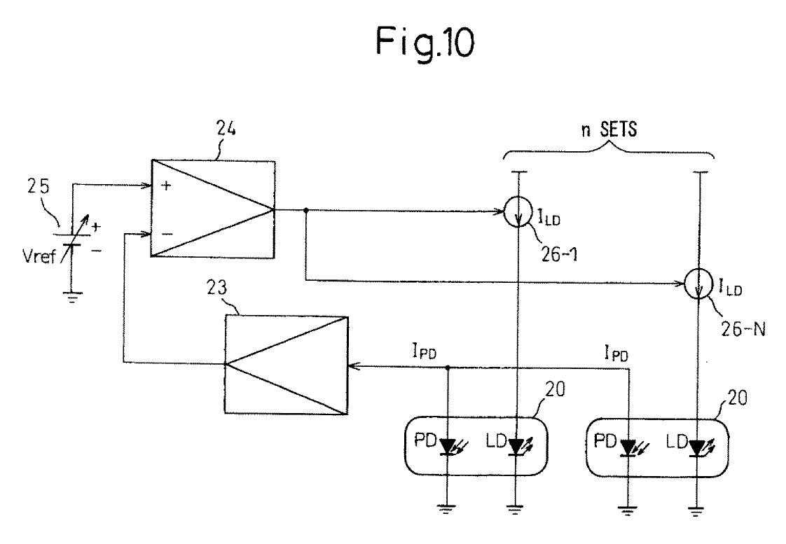

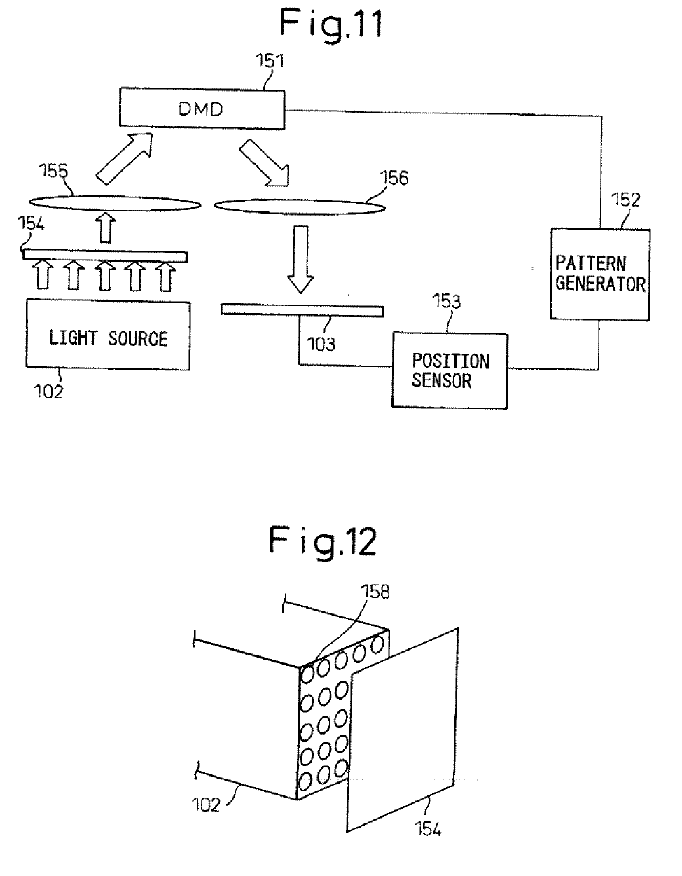

In this way, according to the first embodiment of the present invention, when replacing a degraded or failed laser diode, the laser diode LD and the control board 47 dedicated to that laser diode are replaced together with the corresponding calibration data; as a result, there is no need to adjust the parameters during the replacement, and the replacement can be accomplished easily and quickly. Furthermore, compared with the prior art example described with reference to FIGS. 9 and 10, since only the degraded or failed laser diode can be replaced, the running cost can be minimized.

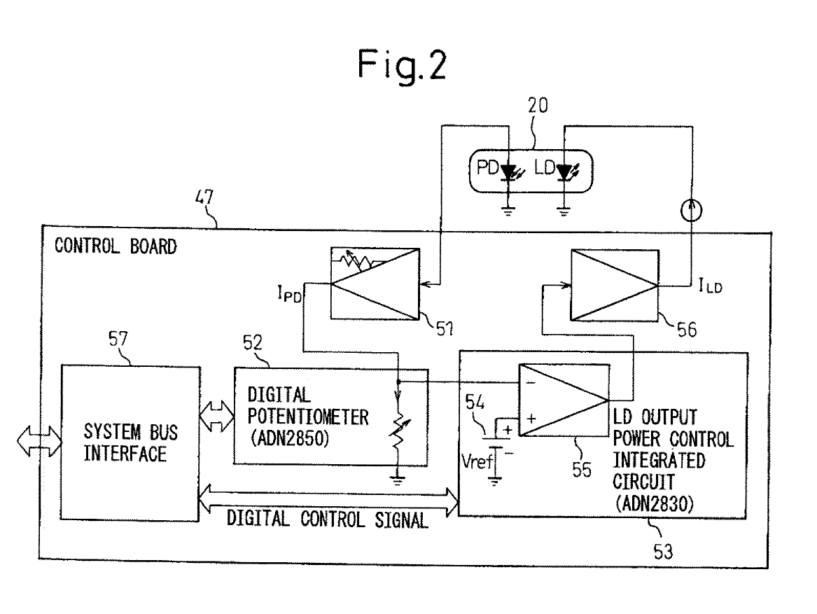

FIG. 2 is a block diagram showing the configuration of the control board shown in FIG. 1. Here, the configuration is shown for one of the control boards 47 connected to the respective modules 20.

A PD output current amplifier 51 not only has the function of amplifying the output current I_{PD} of the photodiode PD, but also acts as a constant-current source that applies a level shift and outputs a current flowing from the positive potential into a digital potentiometer 52. The PD output current amplifier 51 can adjust its current amplification gain by using a semi-fixed resistor, the details of which will be described later.

The digital potentiometer 52 is an integrated circuit whose resistance value can be changed by using a digital signal received via a system bus interface 57. In the example shown in FIG. 2, ADN2850 supplied by Analog Devices, Inc. is used as the digital potentiometer 52. The resistance value of the digital potentiometer 52 is proportional to the earlier described control value. As the control value decreases, the voltage applied to an inverting input terminal of an error amplifier 55 decreases, as a result of which the current I_{LD} supplied to the laser diode LD increases, increasing the light output of the laser diode LD. More specifically, the measured value P₀(X) of the actual light output of the laser diode LD is inversely proportional to the control value X, and equation (1) holds.

$$Po ( X ) = \frac{A}{X} \qquad ( 1 )$$

where A is a constant, and X is an integer ranging from 0 to 1023 in the case of ADN2850 supplied by Analog Devices, Inc. In equation (1), when X=0, in theory P₀(X) will become infinitely large, but in reality, since an internal resistance of several tens of ohms remains in ADN2850, and since the current I_{LD} flowing into the laser diode LD is limited because of its circuit structure, the light output of the laser diode LD does not become infinitely large.

Since the output of the PD output current amplifier 51 is a constant current proportional to the output current I_{PD} of the photodiode PD, a voltage proportional to the output current I_{PD} of the photodiode PD, i.e., a voltage proportional to the light output, is developed across the resistor of the digital potentiometer 52 whose one end is grounded.

The voltage developed by the digital potentiometer 52 is applied to the inverting input terminal of the error amplifier 55. On the other hand, a control voltage Vref set by a reference voltage setter 54 is applied to a noninverting terminal of the error amplifier 55. In the example shown in FIG. 2, ADN2830 supplied by Analog Devices, Inc. is used as an LD output power control integrated circuit (IC) 53 on which the error amplifier 55 and the reference voltage setter 54 are integrated.

The output current of the LD output power control integrated circuit 53 is not only amplified by a current booster 56, but also level-shifted so as to flow from the positive potential to ground, thereby driving the laser diode LD whose cathode is connected with the cathode of PD.

The digital potentiometer 52 can receive via the system bus interface 57 the digital signal for changing the resistance value and can transmit the latched numeric value. In the case of ADN2850, since it supports the communication protocol called the SPI (Serial Peripheral Interface), data transfers are performed in accordance with this communication protocol.

ADN2830 which is used as the LD output power control integrated circuit 53 has the function of detecting the on/off of the output current and the degradation or failure of the laser diode LD. Information concerning the on/off of the output current and the degradation or failure of the laser diode LD can be input and output in the form of a digital signal; in the first embodiment of the present invention, this information is also transferred via the system bus interface 57. Using this ADN2830, the degradation or failure of each individual laser diode LD can be detected in real time. Based on the result of the detection, the user himself can make a decision as to whether the light outputs of the normally operating laser diodes LDs should be increased to compensate for the light output of the degraded or failed laser diode LD and thereby maintain the overall light output of the light source 1, or whether the operation should be immediately stopped to replace the degraded or failed laser diode LD.

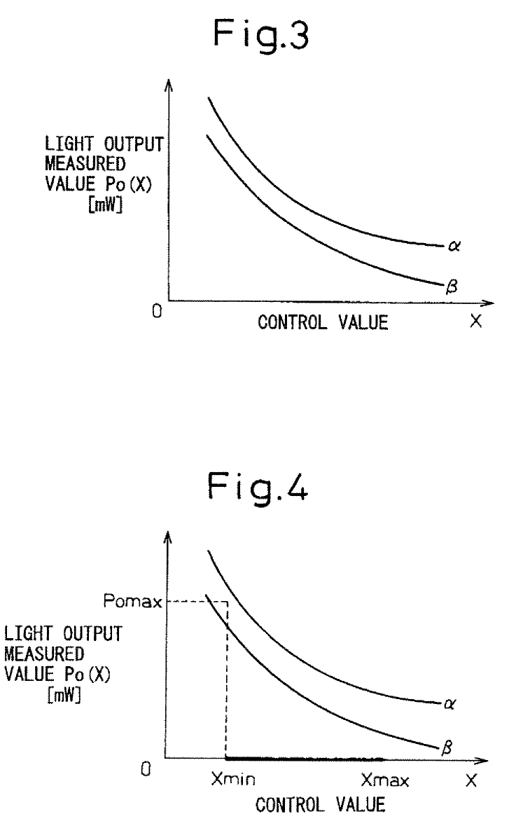

Here, a description will be given of how the circuit parameters are adjusted for the control board 47. FIGS. 3 to 5 are diagrams for explaining the adjustment of the circuit parameters for the circuit board according to the first embodiment of the present invention.

In equation (1), assuming P₀(X) to be a continuous function of X, P₀(X) is differentiated with respect to X, to yield equation (2) below.

$$\frac{d Po ( X )}{d X} = - \frac{A}{{X}^{2}} \qquad ( 2 )$$

Equation (2) defines the rate of change of the measured value P₀(X) of the actual light output of the laser diode LD with respect to the change of the control value X, and its absolute value rapidly increases as the control value X decreases.

Since the control value is a discrete value as earlier described, if “the ratio of the increase of P₀(X) to P₀(X) when the value of X decreases by 1” is defined as “the resolution R(X) [%] of P₀(X),” then equation (3) is obtained as shown below.

$$R ( X ) = \frac{Po ( X - 1 ) - Po ( X )}{Po ( X )} \times 100 [ \% ] \\ ( 2 \leq X ) \qquad ( 3 )$$

The larger the value of R(X), the more difficult the fine adjustment becomes. Substituting equation (1) into equation (3) gives equation (4) below.

$$R ( X ) = \frac{1}{X - 1} \times 100 [ \% ] \\ ( 2 \leq X ) \qquad ( 4 )$$

Equation (4) is a monotonically decreasing function. From equation (4), it can be seen that if, for example, a minimum resolution of 1% is required, the control value X should be set to 101 or larger. Similarly, it can be seen from equation (4) that if, for example, a minimum resolution of 0.5% is required, the control value X should be set to 201 or larger. That is, in the first embodiment of the present invention, once the required resolution is determined, the lower limit of the control value X is automatically determined. For example, in Table 1, values of P₀(X) corresponding to the control values of 100 or less are shown as negative values to indicate that the lower limit of the control value is 101 and control values smaller than that cannot be used.

As earlier explained, the measured value of the actual light output of the laser diode LD differs depending on the combination of the laser diode LD and the control board 47. The graph shown in FIG. 3 indicates that the P₀(X) versus X characteristic differs for different combinations of laser diode LD and control board 47 (the different combinations are indicated by α and β).

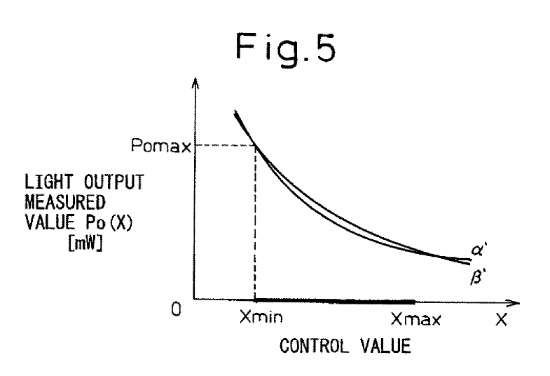

Here, if the constraint that the roughest value of the resolution be guaranteed is imposed, it must also be guaranteed that the maximum value P₀max of the required light output P₀(X) is obtained at the lower limit of the control value X which is determined from equation (4). In FIG. 4, the P₀(X) versus X characteristic for β does not reach P₀max at Xmin, and in this condition, the desired light output cannot be obtained in the vicinity of the control value Xmin. On the other hand, in FIG. 4, the P₀(X) versus X characteristic for α reaches P₀max at Xmin, but the controllable range of P₀(X) is narrow. Therefore, as shown in FIG. 5, the P₀(X) versus X characteristic for β is adjusted in such a manner as to “raise” the curve, while the P₀(X) versus X characteristic for α is adjusted in such a manner as to “lower” the curve. That is, in the first embodiment of the present invention, the adjustment is made so that P₀(X) becomes equal to P₀max at X=Xmin for all the P₀(X) versus X characteristic curves. Here, the adjustment may be made so that P₀(X) becomes exactly equal to P₀max or so that P₀(X) becomes approximately equal to P₀max.

In the PD output current amplifier 51 shown in FIG. 2, the P₀(X) versus X characteristic can be adjusted by adjusting the current amplification gain using the semi-fixed resistor. That is, when the current amplification factor of the PD output current amplifier 51 is increased, the amount of negative feedback increases, so that the P₀(X) versus X characteristic curve lowers. On the other hand, when the current amplification factor of the PD output current amplifier 51 is reduced, the amount of negative feedback decreases, so that the P₀(X) versus X characteristic curve rises.

By adjusting the circuit parameters for the control board 47, that is, by adjusting the P₀(X) versus X characteristic, as described above, the actual light output of the laser diode LD when the control board 47 is driven based on the prescribed control value, i.e., the lower limit value Xmin, becomes identical or close to that of any one of the other laser diodes LDs forming the light source 1. After the adjustment is done, calibration data is generated.

As earlier described, in the first embodiment of the present invention, the degraded or failed laser diode is replaced together with its corresponding control board 47. In a modified example, when the laser diode LD has degraded or failed, if the corresponding control board 47 is not faulty in itself, the control board 47 is used in combination with a new laser diode LD, and the circuit parameters for the control board 47 are adjusted as described above, after which the calibration data is generated; this is economical since the control board 47 can be reused.

In the above first embodiment of the present invention, the calibration data generated for each combination of the laser diode LD, photodiode PD, and control board 47 is prestored in a database connected to the control PC 3 in FIG. 1. And then, the control software running on the control PC 3 reads the calibration data for each particular combination, and controls the light output of the corresponding laser diode LD by communicating with the motherboard 2. According to the first embodiment of the present invention, when replacing a degraded or failed laser diode, the laser diode LD and the control board 47 dedicated to that laser diode are replaced together with the corresponding calibration data.

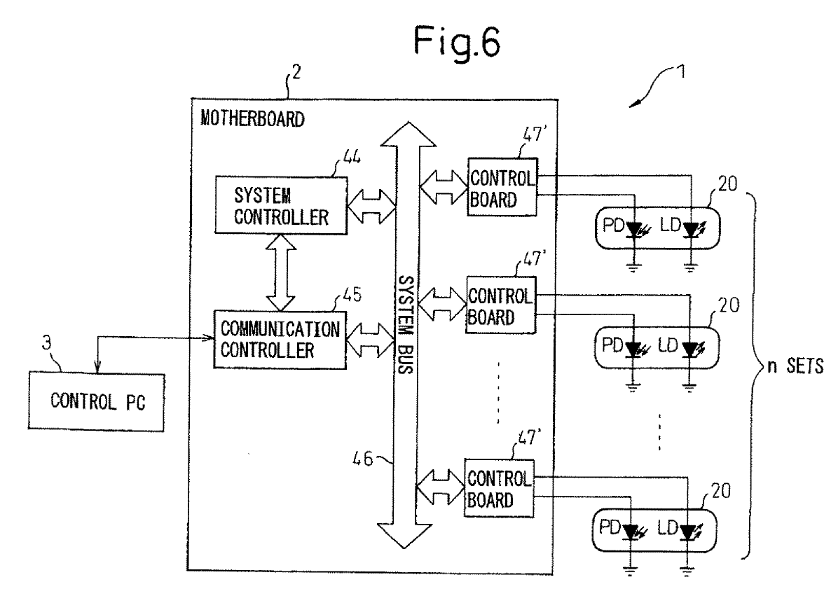

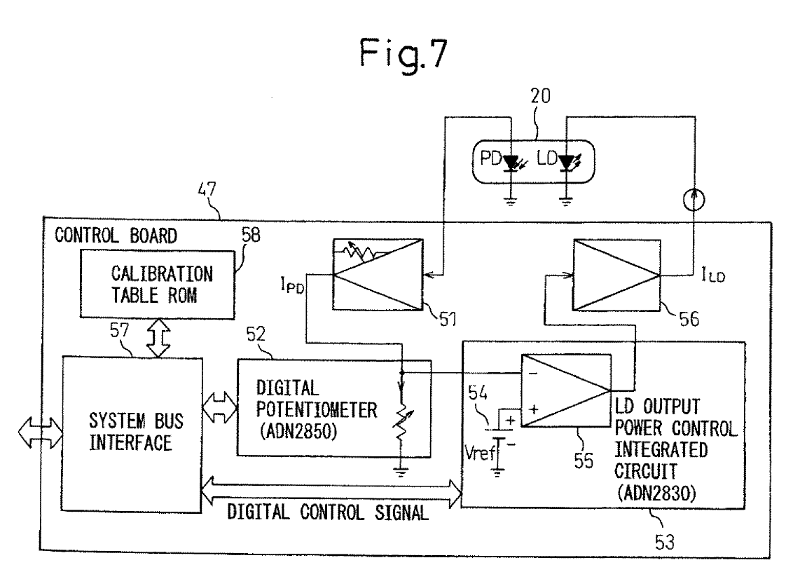

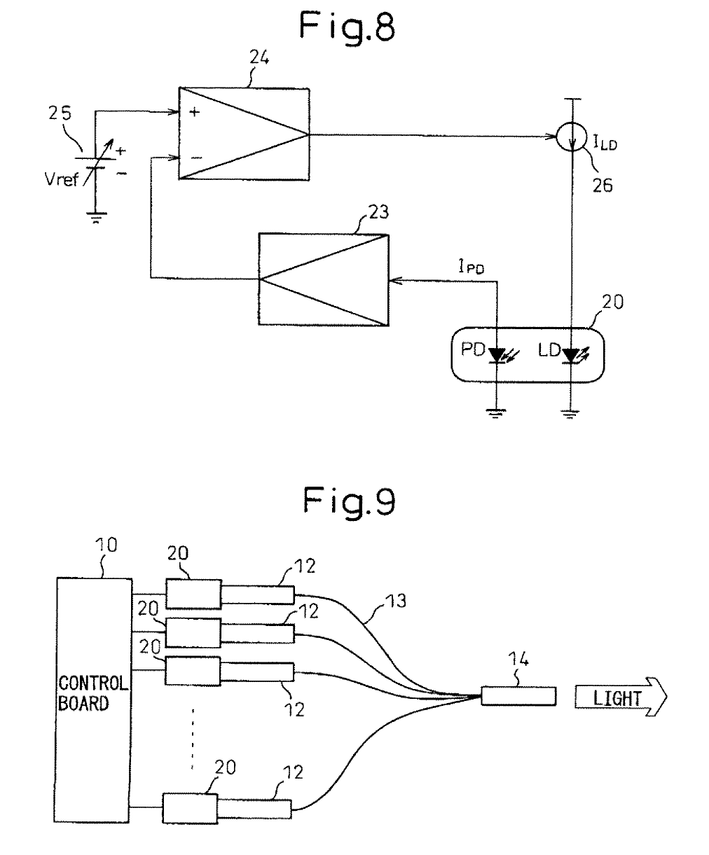

In the first embodiment of the present invention, the calibration data is stored in a database connected to the control PC 3, while in a second embodiment of the present invention, the calibration data is stored in a nonvolatile memory such as an EEPROM on a control board. FIG. 6 is a block diagram showing a light source according to a second embodiment of the present invention and a control board for driving the light source. FIG. 7 is a block diagram showing the configuration of the control board shown in FIG. 6.

In the second embodiment of the present invention, a control board 47′ of FIG. 6 comprises a calibration data ROM 58 for storing calibration data as shown in FIG. 7. The calibration data ROM 58 is connected to a system bus interface 57. The calibration data ROM 58 is a non-volatile memory such as an EEPROM. The calibration data is stored in the calibration data ROM 58 during a calibration process. The contents of the calibration data are as explained in the description of the first embodiment of the present invention.

When the power is on, the control software running on the control PC 3 reads the calibration data from the calibration data ROM 58, via the system bus 46. And then, the control software running on the control PC 3 controls the light output of the corresponding laser diode LD by communicating with the motherboard 2.

In this way, since the control board 47′ has information required for controlling the module 20, a user does not need to setup or replace the calibration data personally.

The above first and second embodiments has been described by dealing with a module structure in which the laser diode and the photodiode are mounted in close proximity to each other. On the other hand, in the case of a discrete laser diode not constructed as a module, the present invention should be applied by mounting a photodiode in close proximity to the laser diode or to any right position where optical power has to be stabilized.

The light source of the present invention may be used to produce light for exposing an exposure surface in a direct exposure apparatus which forms a desired exposure pattern by direct exposure on the exposure surface of an exposure target moving relative to the light source. In particular, when this direct exposure apparatus is an apparatus that forms the desired exposure pattern on the exposure surface by projecting the light from the light source onto a digital micromirror device and by directing the light reflected by the digital micromirror device to the exposure surface of the exposure target moving relative to the digital micromirror device, each of the laser diodes forming the light source of the present invention is controlled so that the light source illuminates the digital micromirror device with evenly distributed light.

The present invention can be applied to a light source constructed from a plurality of laser diodes. According to the present invention, when replacing a designated one of the plurality of laser diodes, since the designated laser diode and the control board dedicated to that laser diode are replaced together with the corresponding calibration data, there is no need to adjust the parameters during the replacement, and the replacement can be accomplished easily and quickly. Furthermore, according to the present invention, since it is easy to replace the degraded or failed laser diode correctly, the running cost can be minimized.

The light source according to the present invention can also be used as the light source for a direct exposure apparatus. According to the direct exposure apparatus, since corrections for the expansion, shrinkage, distortion, misalignment, etc. of the exposure target (exposure target substrate) can be made in real time or in advance at the exposure data generation stage, advantages are achieved including improvement of manufacturing accuracy, improvement of manufacturing yield, reduction of delivery time, and reduction of manufacturing cost.

What is claimed is:

1. A method for controlling a light source constructed from a plurality of laser diodes, comprising:
for each pair consisting of any one of said plurality of laser diodes and a control board dedicated to said one laser diode to control light output of said one laser diode, generating in advance calibration data that defines a correspondence between a control value for driving said control board and a value representing the actual light output of said one laser diode measured when said control board is driven based on said control value; and
controlling overall light output of said light source based on said calibration data generated for said each pair.

2. A method as claimed in claim 1, further comprising adjusting a circuit parameter for said control board so that the actual light output of said laser diode measured when said control board is driven based on said prescribed control value becomes identical or close to the light output of any one of the other laser diodes forming said light source.

3. A method as claimed in claim 2, wherein said light source is used to produce light for exposing an exposure surface in a direct exposure apparatus which forms a desired exposure pattern by direct exposure on the exposure surface of an exposure target moving relative to said light source.

4. A method as claimed in claim 3, wherein said direct exposure apparatus is an apparatus that forms said desired exposure pattern on said exposure surface by projecting the light from said light source onto a digital micromirror device and by directing the light reflected by said digital micromirror device to the exposure surface of said exposure target moving relative to said digital micromirror device, and wherein each of said laser diodes forming said light source is controlled so that said light source illuminates said digital micromirror device with evenly distributed light.

5. A method as claimed in claim 1, wherein said light source is used to produce light for exposing an exposure surface in a direct exposure apparatus which forms a desired exposure pattern by direct exposure on the exposure surface of an exposure target moving relative to said light source.

6. A method as claimed in claim 5, wherein said direct exposure apparatus is an apparatus that forms said desired exposure pattern on said exposure surface by projecting the light from said light source onto a digital micromirror device and by directing the light reflected by said digital micromirror device to the exposure surface of said exposure target moving relative to said digital micromirror device, and wherein
each of said laser diodes forming said light source is controlled so that said light source illuminates said digital micromirror device with evenly distributed light.

7. A method for replacing a designated one of said plurality of laser diodes, for use with a light source constructed from a plurality of laser diodes, wherein
said designated laser diode to be replaced and a control board dedicated to said designated laser diode to control light output of said designated laser diode are respectively replaced with a new laser diode and a new control board dedicated to said new laser diode to control light output of said new laser diode, and
among calibration data which, for each pair consisting of any one of said plurality of laser diodes and a control board dedicated to said one laser diode to control the light output of said one laser diode, defines a correspondence between a control value for driving said control board and a value representing the actual light output of said one laser diode measured when said control board is driven based on said control value, said calibration data being used for controlling overall light output of said light source, the calibration data that has been used for controlling the light output of said designated laser diode is replaced with the calibration data generated for the pair consisting of said new laser diode and said new control board dedicated to said new laser diode to control the light output of said new laser diode.

8. A method as claimed in claim 7, wherein said calibration data is generated by preadjusting a circuit parameter for said control board so that the actual light output of said laser diode measured when said control board is driven based on said prescribed control value becomes identical or close to the light output of any one of the other laser diodes forming said light source.

9. A method as claimed in claim 8, wherein said light source is used to produce light for exposing an exposure surface in a direct exposure apparatus which forms a desired exposure pattern by direct exposure on the exposure surface of an exposure target moving relative to said light source.

10. A method as claimed in claim 9, wherein said direct exposure apparatus is an apparatus that forms said desired exposure pattern on said exposure surface by projecting the light from said light source onto a digital micromirror device and by directing the light reflected by said digital micromirror device to the exposure surface of said exposure target moving relative to said digital micromirror device, and wherein
each of said laser diodes is controlled so that said light source illuminates said digital micromirror device with evenly distributed light.

11. A method as claimed in claim 7, wherein said light source is used to produce light for exposing an exposure surface in a direct exposure apparatus which forms a desired exposure pattern by direct exposure on the exposure surface of an exposure target moving relative to said light source.

12. A method as claimed in claim 11, wherein said direct exposure apparatus is an apparatus that forms said desired exposure pattern on said exposure surface by projecting the light from said light source onto a digital micromirror device and by directing the light reflected by said digital micromirror device to the exposure surface of said exposure target moving relative to said digital micromirror device, and wherein
each of said laser diodes is controlled so that said light source illuminates said digital micromirror device with evenly distributed light.

13. A light source constructed from a plurality of laser diodes, wherein
overall light output of said light source is controlled based on calibration data which is generated in advance for each pair consisting of any one of said plurality of laser diodes and a control board dedicated to said one laser diode to control the light output of said one laser diode, and which defines a correspondence between a control value for driving said control board and a value representing the actual light output of said one laser diode measured when said control board is driven based on said control value.

14. A light source as claimed in claim 13, wherein a circuit parameter for said control board is adjusted so that the actual light output of said laser diode measured when said control board is driven based on said prescribed control value becomes identical or close to the light output of any one of the other laser diodes forming said light source.

15. A light source as claimed in claim 14, wherein said light source is used to produce light for exposing an exposure surface in a direct exposure apparatus which forms a desired exposure pattern by direct exposure on the exposure surface of an exposure target moving relative to said light source.

16. A light source as claimed in claim 15, wherein said direct exposure apparatus is an apparatus that forms said desired exposure pattern on said exposure surface by projecting the light from said light source onto a digital micromirror device and by directing the light reflected by said digital micromirror device to the exposure surface of said exposure target moving relative to said digital micromirror device, and wherein
each of said laser diodes forming said light source is controlled so that said light source illuminates said digital micromirror device with evenly distributed light.

17. A light source as claimed in claim 13, wherein said light source is used to produce light for exposing an exposure surface in a direct exposure apparatus which forms a desired exposure pattern by direct exposure on the exposure surface of an exposure target moving relative to said light source.

18. A light source as claimed in claim 17, wherein said direct exposure apparatus is an apparatus that forms said desired exposure pattern on said exposure surface by projecting the light from said light source onto a digital micromirror device and by directing the light reflected by said digital micromirror device to the exposure surface of said exposure target moving relative to said digital micromirror device, and wherein
each of said laser diodes forming said light source is controlled so that said light source illuminates said digital micromirror device with evenly distributed light.
